(19) United States
(12) Patent Application Publication
(10) Pub. No.: US 2025/0287596 A1
(43) Pub. Date: Sep. 11, 2025

(54) MEMORY DEVICE AND METHOD OF MANUFACTURING MEMORY DEVICE

(71) Applicant: Kioxia Corporation, Tokyo (JP)

(72) Inventors: Susumu HASHIMOTO, Yokkaichi Mie (JP); Masayoshi TAGAMI, Kuwana Mie (JP); Keisuke NAKATSUKA, Kuwana Mie (JP); Hiroshi SHINOHARA, Yokosuka Kanagawa (JP); Yasuhiro HIRASHIMA, Kawasaki Kanagawa (JP)

(73) Assignee: Kioxia Corporation, Tokyo (JP)

(21) Appl. No.: 18/829,341

(22) Filed: Sep. 10, 2024

(30) Foreign Application Priority Data
Mar. 7, 2024 (JP) 2024-035168

(51) Int. Cl. H10B 43/35; G11C 16/04; H10B 43/10; H10B 43/27

(52) U.S. Cl. CPC H10B 43/35; G11C 16/0483; H10B 43/10; H10B 43/27

(57) ABSTRACT

A first transistor is on the first substrate. A second substrate is above the first transistor. An external connection terminal is above the second substrate. A second transistor is on the second substrate. A first conductor penetrates the second substrate and electrically couples the first transistor to the external connection terminal. A first isolation structure, as viewed from a first direction, is ring-shaped and surrounds the first conductor, penetrates the second substrate, and isolates the second substrate. A memory cell array is electrically coupled to the first transistor and the second transistor.

### CROSS-REFERENCE TO RELATED APPLICATIONS

This application is based upon and claims the benefit of priority from Japanese Patent Application No. 2024-35168, filed Mar. 7, 2024, the entire contents of which are incorporated herein by reference.

### FIELD

Embodiments described herein relate generally to a memory device and a method of manufacturing the memory device.

### BACKGROUND

A memory device including memory cells arranged in three dimensions is known. The memory device can have a structure in which structures including elements formed in separate processes on separate substrates are joined to achieve a large memory capacity.

### BRIEF DESCRIPTION OF DRAWINGS

FIG. 1 illustrates an example of components of a memory device and coupling of the components of a first embodiment.

FIG. 2 illustrates components and coupling of the components of a single block of the memory device of the first embodiment.

FIG. 3 illustrates an exterior of the memory device of the first embodiment.

FIG. 4 illustrates an example of the structure of some planes of the memory device of the first embodiment.

FIG. 5 illustrates an example of a partial sectional structure of the memory device of the first embodiment.

FIG. 6 illustrates an example of a section of a memory pillar of the memory device of the first embodiment.

FIG. 7 illustrates an example of a partial sectional structure of the memory device of the first embodiment.

FIG. 8 is a plan view of a portion of the memory device of the first embodiment.

FIG. 9 illustrates an example of a flow of a method of manufacturing the memory device of the first embodiment.

FIGS. 10, 11, 12, 13, 14, and 15 illustrate examples of states during the manufacturing of a part of the memory device of the first embodiment.

FIG. 16 is a plan view of a portion of the memory device of the first embodiment.

FIG. 17 is a plan view of a portion of the memory device of modification 1 of the first embodiment.

FIG. 18 illustrates an example of a partial sectional structure of the memory device of modification 2 of the first embodiment.

FIG. 19 illustrates an example of a partial sectional structure of the memory device of modification 3 of the first embodiment.

FIG. 20 illustrates an example of a partial sectional structure of a memory device of a second embodiment.

FIGS. 21, 22, 23, 24, and 25 illustrate examples of states during the manufacturing of a portion of the memory device of the second embodiment.

FIGS. 26, 27, 28, 29, 30, and 31 illustrate examples of states during the manufacturing of a portion of the memory device of a modification of the second embodiment.

FIGS. 32 and 33 illustrate examples of a partial sectional structure of a memory device of a third embodiment.

FIGS. 34 and 35 illustrate examples of a partial sectional structure of a memory device of a fourth embodiment.

FIG. 36 illustrates an example of a partial sectional structure of the memory device of a modification.

### DETAILED DESCRIPTION

In general, according to one embodiment, a memory device includes a first substrate, a first transistor on the first substrate, a second substrate above the first transistor, an external connection terminal above the second substrate, a second transistor on the second substrate, a first conductor, a first isolation structure, and a memory cell array electrically coupled to the first transistor and the second transistor. The first conductor penetrates the second substrate and electrically couples the first transistor to the external connection terminal. The first isolation structure, as viewed from a first direction, is ring-shaped and surrounds the first conductor, penetrates the second substrate, and isolates the second substrate.

Embodiments will now be described with reference to the figures. In order to distinguish components having substantially the same function and configuration in an embodiment or over different embodiments from each other, an additional numeral or letter may be added to the end of each reference numeral or letter. The entire description of a particular embodiment applies to another embodiment unless an explicit mention is made otherwise, or an obvious elimination is involved.

The figures are schematic, and the relation between the thickness and the area of a plane of a layer and the ratio of thicknesses of layers may differ from those in actuality. The figures may include components which differ in relations and/or ratios of dimensions in different figures.

Steps in the flow of a method according to an embodiment are not limited to any of the illustrated orders, and may occur in an order different from the illustrated orders and/or may occur concurrently with another step or steps.

The specification and the claims, when mentioning that a particular (first) component is “coupled” to another (second) component, intend to cover both the form of the first component directly coupled to the second component and the form of the first component coupled to the second component via one or more components which are always or selectively conductive.

The embodiments will be described using an X-Y-Z orthogonal coordinate system. The x axis extends in the X direction. The y axis extends in the Y direction. The z axis extends in the Z direction.

### 1. First Embodiment

### 1.1. Configuration (Structure)

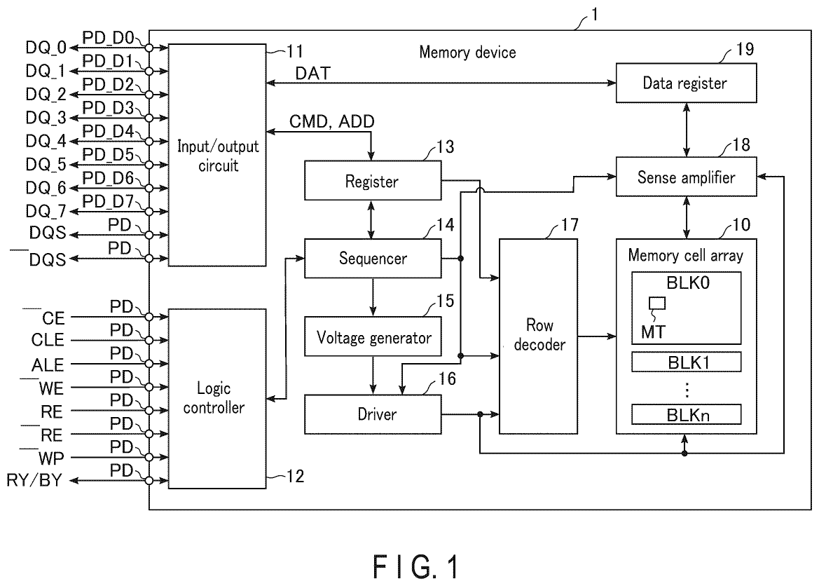

FIG. 1 illustrates an example of components and coupling of the components of a memory device of a first embodiment. The memory device 1 is a device that uses memory cells to store data. The memory device 1 operates based on a command CMD and address information ADD received from an external memory controller. The memory device 1 receives data DAT to be written and outputs data stored in the memory device 1.

The memory device 1 includes components such as a memory cell array 10, an input/output circuit 11, a logic controller 12, a register 13, a sequencer 14, a voltage generator 15, a driver 16, a row decoder 17, a sense amplifier 18, a data register (or, data cache) 19, and a plurality of external connection terminals (or, pads) PD.

The memory cell array 10 is a set of arrayed memory cells. The memory cell array 10 includes a plurality of memory blocks (or, blocks) BLK,. Each block BLK includes a plurality of memory cell transistors MT. In an area in which the memory cell array 10 is provided, interconnects such as word lines WL (not shown) and bit lines BL (not shown) are also located.

The memory cell array 10 is a set of arrayed memory cells. The memory cell array 10 includes a plurality of memory blocks (or, blocks) BLK. Each block BLK includes a plurality of memory cell transistors MT. In an area in which the memory cell array 10 is provided, interconnects such as word lines WL (not shown) and bit lines BL (not shown) are also located.

The input/output circuit 11 transmits and receives various signals to and from the outside of the memory device 1, for example, a memory controller. The input/output circuit 11 is coupled to the external connection terminals PD. The input/output circuit 11 transmits and receives input/output signals DQ_0, DQ_1, DQ_2, DQ_3, DQ_4, DQ_5, DQ_6, and DQ_7 at the external connection terminals PD_D0, PD_D1, PD_D2, PD_D3, PD_D4, PD_D5, PD_D6, and PD_D7, respectively. The input/output circuit 11 transmits and receives signals DQS and ⁻DQS at the external connection terminals PD. The symbol “⁻” indicates inverted logic of logic of a signal of a name without the symbol “⁻”, and indicates that a signal is asserted if the signal whose name includes the symbol “⁻” is at a low (“L”) level. The set of input/output signals DQ_0 to DQ_7 transmits a command (CMD), write data or read data (DAT), address information (ADD), and status (STA). The signals DQS and ⁻DQS indicate the timing of taking in the input/output signals DQ_0 to DQ_7.

The logic controller 12 transmits and receives signals to and from the outside of the memory device 1, for example, a memory controller. The logic controller 12 is coupled to the external connection terminals PD and transmits and receives the signals ⁻CE, CLE, ALE, ⁻WE, RE, ⁻RE, WP, and RY/BY at the external connection terminals PD. The signal ⁻CE enables the memory device 1. The signal CLE notifies the memory device 1 of the transmission of the command by the input/output signal DQ. The signal ALE notifies the memory device 1 of the transmission of the address information ADD by the input/output signal DQ. The signal ⁻WE instructs the memory device 1 to take in the input/output signal DQ. The signal ⁻RE instructs the memory device 1 to output the input/output signal DQ. The ready/busy signal RY/BY indicates whether the memory device 1 is in a ready state or in a busy state, and indicates a busy state by a low level. When the memory device 1 is in the ready state, the memory device 1 accepts the command. When the memory device 1 is in the busy state, the memory device 1 does not accept the command.

The register 13 is a circuit that holds the command CMD and the address information ADD received by the memory device 1. The command CMD instructs the sequencer 14 to perform various operations including data read, data write, and data erase. The address information

ADD includes, in one example, a block address, a page address, and a column address. The block address, the page address, and the column address designate the block BLK, the word line WL, and the bit line BL, respectively. The sequencer 14 is a circuit that controls an

operation of the entirety of the memory device 1. Based on the command CMD received from the register 13, the sequencer 14 controls the voltage generator 15, row decoder 17 and sense amplifier 18, and executes various operations including data read, data write and data erase.

The voltage generator 15 is a circuit that generates a plurality of voltages with different magnitudes. The voltage generator 15 receives a power supply voltage from an outside of the memory device 1, and generates a plurality of voltages from the power supply voltage. The generated voltages are supplied to components such as the driver 16.

The driver 16 is a circuit that applies various voltages necessary for the operation of the memory device 1 to several components. The driver 16 receives a plurality of voltages from the voltage generator 15 and supplies the received voltages to the memory cell array 10, the row decoder 17, and the sense amplifier 18.

The row decoder 17 is a circuit for selecting a block BLK. The row decoder 17 transfers the voltage supplied from the driver 16 to a single block BLK selected based on the block address received from the register 13.

The sense amplifier 18 is a circuit that determines data stored in the memory cell array 10. The sense amplifier 18 senses the state of the memory cell transistor MT, generates read data based on the sensed state, or transfers write data to the memory cell transistor MT.

The data register 19 is a circuit that holds data for input and output of data by the memory device 1. The data register 19 receives the data DAT received by the memory device 1 and supplies data based on the received data DAT to the sense amplifier 18. The data register 19 receives data from the sense amplifier 18 and supplies the data DAT based on the received data to the input/output circuit 11.

### 1.1.1. Memory Cell Array

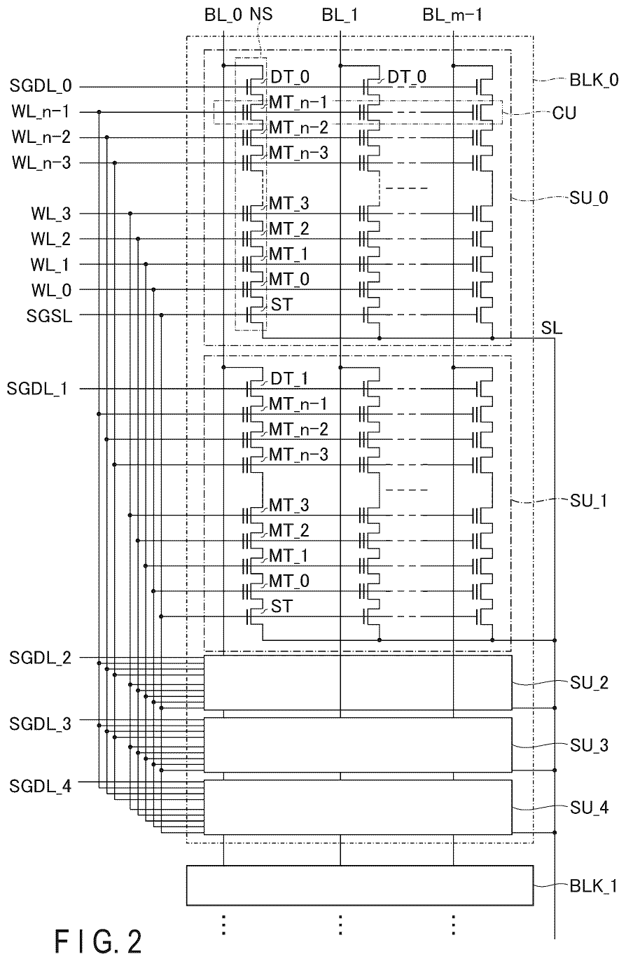

FIG. 2 illustrates components of a single block BLK_ 0 of the memory device 1 of the first embodiment, and a coupling of the components. A plurality of blocks BLK, for example, all blocks BLK, include the components and the coupling illustrated in FIG. 2.

A single block BLK includes a plurality of string units SU. FIG. 2 illustrates an example of five string units SU_0 to SU_4.

As illustrated in FIG. 2, each of an m-number of bit lines BL_0 to BL_m-1 is coupled, in each block BLK, to a single NAND string NS from each of string units SU_0 to SU_4., where m is a positive integer.

Each NAND string NS includes a single select gate transistor ST, n-number of memory cell transistors MT, and a single select gate transistor DT (DT0, DT1, DT2, DT3, or DT4), where n is a positive integer. The memory cell transistor MT is an element that stores data in a non-volatile manner. The memory cell transistor MT includes a control gate electrode or gate electrode (or, word line WL) and a charge accumulation film insulated from the surrounding, and stores data in a non-volatile manner based on charge in the charge accumulation film. Data is written to the memory cell transistor MT by injecting electrons into the charge accumulation film. The select gate transistors ST, memory cell

transistors MT_0 to MT_n-1, and select gate transistor DT are coupled in series in the named order between a source line SL and a single bit line BL.

A plurality of NAND strings NS respectively coupled a plurality of different bit lines BL constitute a single string unit SU. In each string unit SU, the control gate electrodes of the memory cell transistors MT_0 to MT_n-1 are coupled to the word lines WL_0 to WL_n-1, respectively. A set of memory cell transistors MT, which share a single word line WL in one string unit SU, is called “cell unit CU”.

The select gate transistors DT0 to DT4 belong to the string units SU_0 to SU_4, respectively. In FIG. 2, the select gate transistors DT2, DT3, and DT4 are not illustrated. The gate of the select gate transistor DT0 of each of the NAND strings NS of the string unit SU_0 is coupled to a select gate line SGDL0. Similarly, the gates of the select gate transistors DT1, DT2, DT3, and DT4 of the respective NAND strings NS of the string units SU_1, SU_2, SU_3, and SU_4 are coupled to select gate lines SGDL1, SGDL2, SGDL3, and SGDL4.

The gate of the select gate transistor ST is coupled to a select gate line SGSL.

### 1.1.2. Structure of Memory Device

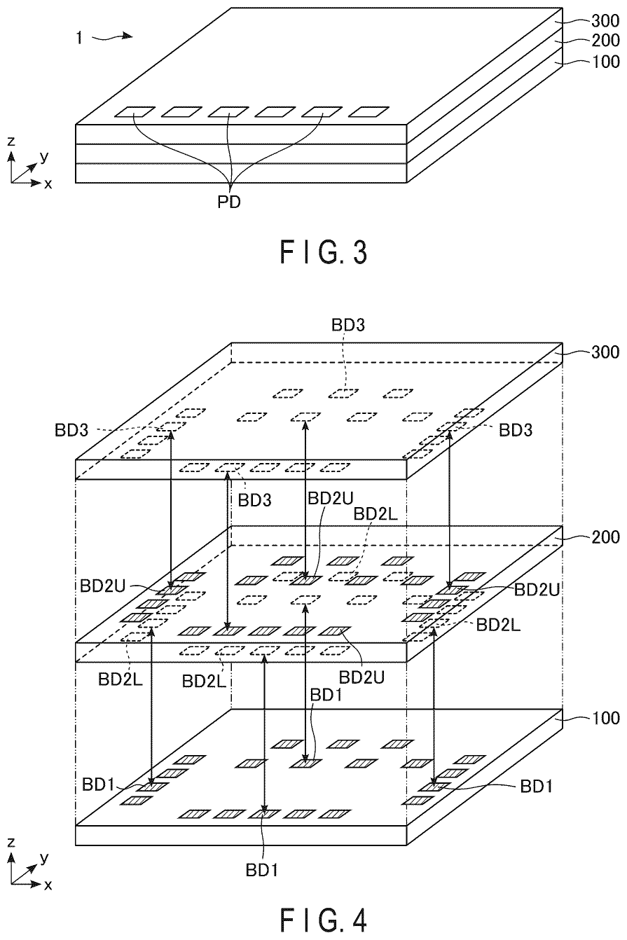

FIG. 3 illustrates an exterior of the memory device of the first embodiment. As illustrated in FIG. 3, the memory device 1 includes a first structure 100, a second structure 200, and a third structure 300 arranged along the z axis. The first structure 100, the second structure 200, and the third structure 300 spread along the xy plane and are arranged along the Z axis. The second structure 200 is located on the upper surface of the first structure 100. The third structure 300 is located on the upper surface of the second structure 200.

The first structure 100, the second structure 200, and the third structure 300 each include a plurality of semiconductors, a plurality of various conductors, and a plurality of insulators formed on the substrate using the substrate. The first structure 100, the second structure 200, and the third structure 300 each include a plurality of elements and interconnects implemented by semiconductors, conductors, and insulators. The first structure 100, the second structure 200, and the third structure 300 each include an electric circuit including elements and interconnects. The elements and interconnects in the first structure 100, the elements and interconnects in the second structure 200, and the elements and interconnects in the third structure 300 are electrically coupled to each other.

The set of the first structure 100 and the second structure 200 includes the input/output circuit 11, the logic controller 12, the register 13, the sequencer 14, the voltage generator 15, the driver 16, the row decoder 17, the sense amplifier 18, and the data register 19. The first structure 100 can include any one or ones of the input/output circuit 11, the logic controller 12, the register 13, the sequencer 14, the voltage generator 15, the driver 16, the row decoder 17, the sense amplifier 18, and the data register 19. The second structure 200 can include any one or ones of the input/output circuit 11, the logic controller 12, the register 13, the sequencer 14, the voltage generator 15, the driver 16, the row decoder 17, the sense amplifier 18, and the data register 19.

The third structure 300 includes the memory cell array 10 and the plurality of external connection terminals PD. The external connection terminals PD are exposed on the upper surface of the third structure 300.

FIG. 4 illustrates an example of the structure of some planes of the memory device of the first embodiment. FIG. 4 illustrates an exploded view of the structure of FIG. 3.

As illustrated in FIG. 4, the first structure 100 includes a plurality of conductive joint terminals BD1. The joint terminals BD1 are exposed on the upper surface of the first structure 100. The joint terminals

BD1 are coupled to elements inside the first structure 100.

The second structure 200 includes a plurality of conductive joint terminals BD2L and a plurality of conductive joint terminals BD2U. The joint terminals BD2L are exposed on the lower surface of the second structure 200. The joint terminals BD2L are coupled to elements inside the second structure 200. The joint terminals BD2L have the same layout as layout of the joint terminals BD1 of the first structure 100. The joint terminals BD2L are arranged such that when the first structure 100 and the second structure 200 are joined, each joint terminal BD2L makes contact with one of the joint terminals BD1 of the first structure 100 corresponding to the joint terminal BD2L. A specific joint terminal BD2L and the one of the joint terminals BD1 of the first structure 100 corresponding to the specific joint terminal BD2L are elements that function as the same node in the circuit.

The joint terminals BD2U are exposed on the upper surface of the second structure 200. The joint terminals BD2U are coupled to elements inside the second structure 200.

The third structure 300 includes a plurality of conductive joint terminals BD3. The joint terminals BD3 are exposed on the lower surface of the third structure 300. The joint terminals BD3 are coupled to elements inside the third structure 300. The joint terminals BD3 have the same layout as layout of the joint terminals BD2U of the second structure 200. The joint terminals BD3 are arranged such that when the second structure 200 and the third structure 300 are joined, each joint terminal BD3 makes contact with one of the joint terminals BD2U of the second structure 200 corresponding to the joint terminal BD3. A specific joint terminal BD3 and the one of the joint terminals BD2U of the second structure 200 corresponding to the specific joint terminal BD3 are elements that function as the same node in the circuit.

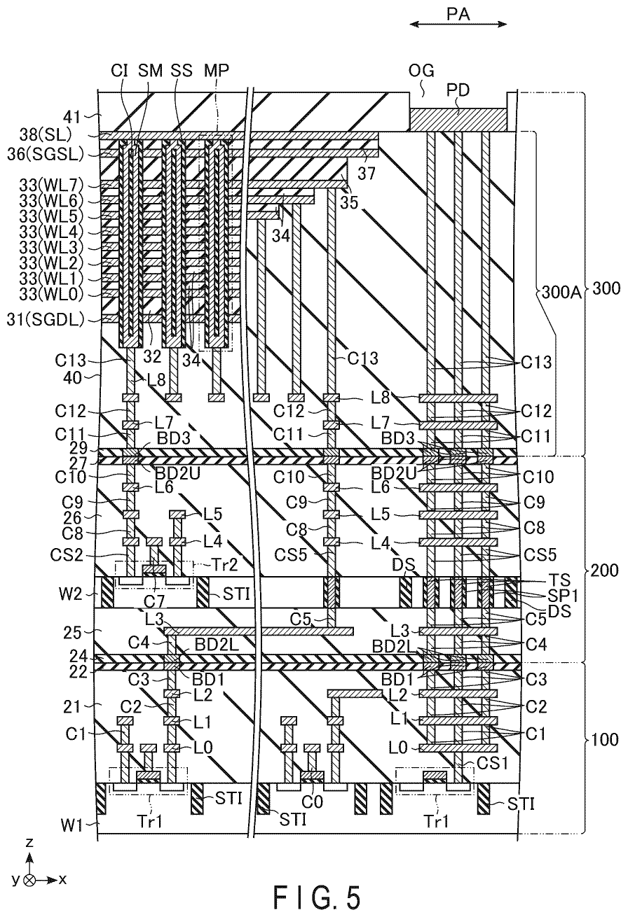

FIG. 5 illustrates an example of a partial sectional structure of the memory device of the first embodiment. As illustrated in FIG. 5, the memory device 1 includes a connection region PA. The connection region PA is a region in which the conductors electrically connected to the external connection terminals PD are located. The connection region PA extends along the x, y, and z axes.

The first structure 100 further includes a substrate W1, a structure STI, a transistor Tr1, contacts CS1, C0, C1, C2, and C3, conductors L0, L1, and L2, and insulators 21 and 22. In the following description, the conductor also includes a semiconductor which has conductivity by containing impurities. In one example, the substrate W1 contains silicon. In one example, the contacts CS1, C0, C1, C2, and C3, and the conductors L0, L1, and L2 contain copper or tungsten. In one example, the insulators 21 and 22 include silicon oxide.

The structure STI will hereinafter be simply referred to as STI. The STI extends along the z axis from the upper surface of the substrate W1 in the substrate W1. In one example, the STI includes silicon oxide.

The transistor Tr1 is located in the region above and near the upper surface of the substrate W1. The transistor Tr1 includes a gate insulator on the upper surface of the substrate W1, a gate electrode on the upper surface of the gate insulator, and a pair of source/drain regions sandwiching the region below the gate electrode.

Each contact C0 is in contact with the upper surface of the gate electrode of a single transistor Tr1 on the lower surface. Each contact CS1 is in contact with a single source/drain region on the lower surface.

Each conductor L0 is in contact with a single contact C0 or CS1 on the lower surface.

Each contact C1 is in contact with the upper surface of a single conductor LO on the lower surface. A plurality of contacts C1 in the connection region PA is in contact with the upper surface of a single conductor L0 on respective lower surfaces.

Each conductor L1 is in contact with the upper surface of a single contact C1 on the lower surface. A single conductor L1 in the connection region PA is in contact with the upper surface of each of the plurality of contacts C1 on the lower surface.

Each contact C2 is in contact with the upper surface of a single conductor L1 on the lower surface. A plurality of contacts C2 in the connection region PA is in contact with the upper surface of a single conductor L1 on respective lower surfaces.

Each conductor L2 is in contact with the upper surface of a single contact C2 on the lower surface. A single conductor L2 in the connection region PA is in contact with the upper surface of each of the plurality of contacts C2 on the lower surface.

Each contact C3 is in contact with the upper surface of a single conductor L2 on the lower surface. A plurality of contacts C3 in the connection region PA is in contact with the upper surface of a single conductor L2 on respective lower surfaces.

A set of the transistor Tr1, the contacts CS1, C0, C1, C2, and C3, and the conductors L0, L1, and L2 implements a circuit included in the first structure 100. Therefore, the first structure 100 includes the transistor Tr1, the contacts CS1, C0, C1, C2, and C3, and the conductors L0, L1, and L2, which have any shapes and arrangements to implement the circuit included in the first structure 100.

The insulator 21 ranges from the level of the upper surface of the substrate W1 to the level of the upper surface of the contact C3. The insulator 21 fills the region of the first structure 100 where components are not provided, that is, the region where the transistor Tr1, the contacts CS1, C0, C1, C2, and C3, and the conductors L0, L1, and L2 are not provided.

Each joint terminal BD1 is in contact with the upper surface of a single contact C3 on the lower surface. The insulator 22 fills the region in the layer in which the joint terminal BD1 is located where the joint terminal BD1 is not provided.

The second structure 200 further includes a substrate W2, a structure STI, a transistor Tr2, contacts CS2, CS5, C4, C5, C7, C8, C9, and C10, conductors L3, L4, L5, and L6, and insulators 24, 25, 26, and 27. In one example, the substrate W2 includes silicon. In one example, the contacts CS2, CS5, C4, C5, C7, C8, C9, and C10, and the conductors L3, L4, L5, and L6 include copper or tungsten. In one example, the insulators 24, 25, 26, and 27 include silicon oxide.

Each joint terminal BD2L is located in the lowermost layer of the second structure 200. The insulator 24 fills the region in the layer in which the joint terminal BD2L is located where the joint terminal BD2L is not provided.

Each contact C4 is in contact with the upper surface of a single joint terminal BD2L on the lower surface.

Each conductor L3 is in contact with the upper surface of a single contact C4 on the lower surface. A single conductor L3 in the connection region PA is in contact with the upper surface of each of the plurality of contacts C4 on the lower surface. Each contact C5 is in contact with the upper

surface of a single conductor L3 on the lower surface. A plurality of contacts C5 in the connection region PA is in contact with the upper surface of a single conductor L3 on respective lower surfaces.

The insulator 25 ranges from the level of the upper surface of the joint terminal BD2L and the upper surface of the insulator 24 to the level of the upper surface of the contact C5. The insulator 25 fills the region above the joint terminal BD2L and the insulator 24 where the contacts C4 and C5 and the conductor L3 are not provided. In one example, the insulator 25 includes silicon oxide.

The substrate W2 is located on the upper surface of the insulator 25. The STI penetrates the substrate W2 across the upper surface and the lower surface of the substrate W2.

Vias TS penetrate the substrate W2 across the upper surface and the lower surface of the substrate W2. Each via TS is in contact with the upper surface of a single contact C5 on the lower surface.

The insulator SP1 penetrates the substrate W2 across the upper surface and the lower surface of the substrate W2. Each insulator SP1 covers the side surface of a single via TS.

An isolation structure DS electrically isolates the region surrounded by the isolation structure DS in the substrate W2 from the region outside the region surrounded by the isolation structure DS in the substrate W2. The isolation structure DS surrounds a plurality of sets of the via TS and the insulator SP1 in the connection region PA. The isolation structure DS penetrates the substrate W2 across the upper surface and the lower surface of the substrate W2. The isolation structure DS includes an insulator, and in one example includes silicon oxide.

The transistor Tr2 is located in the region above and near the upper surface of the substrate W2. The transistor Tr2 includes a gate insulator on the upper surface of the substrate W2, a gate electrode on the upper surface of the gate insulator, and a pair of source/drain regions sandwiching the region below the gate electrode.

Each contact C7 is in contact with the upper surface of the gate electrode of a single transistor Tr2 on the lower surface. Each contact CS2 is in contact with a single source/drain region on the lower surface. Each contact CS5 is in contact with the upper surface of a single via TS on the lower surface.

Each conductor L4 is in contact with the upper surface of a single contact C7, CS2, or CS5 on the lower surface. A single conductor L4 in the connection region PA is in contact with the upper surface of each of the plurality of contacts CS5 on the lower surface.

Each contact C8 is in contact with the upper surface of a single conductor L4 on the lower surface. A plurality of contacts C8 in the connection region PA is in contact with the upper surface of a single conductor L4 on respective lower surfaces.

Each conductor L5 is in contact with the upper surface of a single contact C8 on the lower surface. A single conductor L5 in the connection region PA is in contact with the upper surface of each of the plurality of contacts C8 on the lower surface.

Each contact C9 is in contact with the upper surface of a single conductor L5 on the lower surface. A plurality of contacts C9 in the connection region PA is in contact with the upper surface of a single conductor L5 on respective lower surfaces.

Each conductor L6 is in contact with the upper surface of a single contact C9 on the lower surface. A single conductor L6 in the connection region PA is in contact with the upper surface of each of the plurality of contacts C9 on the lower surface.

Each contact C10 is in contact with the upper surface of a single conductor L6 on the lower surface. A plurality of contacts C10 in the connection region PA is in contact with the upper surface of a single conductor L6 on respective lower surfaces.

A set of the transistor Tr2, the contacts CS2, CS5, C7, C8, C9, and C10, and the conductors L4, L5, and L6 implements a circuit included in the second structure 200. Therefore, the second structure 200 includes the transistor Tr2, the contacts CS2, CS5, C7, C8, C9, and C10, and the conductors L4, L5, and L6, which have any shapes and arrangements to implement the circuit included in the second structure 200.

The insulator 26 ranges from the level of the upper surface of the substrate W2 to the level of the upper surface of the contact C10. The insulator 26 fills the region from the level of the upper surface of the substrate W2 to the level of the upper surface of the contact C10 where components are not provided, that is, the region where the transistor Tr2, the contacts CS2, CS5, C7, C8, C9, and C10, and the conductors L4, L5, and L6 are not provided.

Each joint terminal BD2U is in contact with the upper surface of a single contact C10 on the lower surface. The insulator 27 fills the region in the layer in which the joint terminal BD2U is located where the joint terminal BD2U is not provided.

The third structure 300 further includes contacts C11, C12, and C13, conductors L7, L8, 31, 33, 36, 38, insulators 29, 34, 35, 37, 40, and 41, and a memory pillar MP.

Each joint terminal BD3 is located in the lowermost layer of the third structure 300. The insulator 29 fills the region in the layer in which the joint terminal BD3 is located where the joint terminal BD3 is not provided.

Each contact C11 is in contact with the upper surface of a single joint terminal BD3 on the lower surface.

Each conductor L7 is in contact with the upper surface of a single contact C11 on the lower surface. A single conductor L7 in the connection region PA is in contact with the upper surface of each of the plurality of contacts C11 on the lower surface.

Each contact C12 is in contact with the upper surface of a single conductor L7 on the lower surface. A plurality of contacts C12 in the connection region PA is in contact with the upper surface of a single conductor L7 on respective lower surfaces.

Each conductor L8 is in contact with the upper surface of a single contact C12 on the lower surface. A single conductor L8 in the connection region PA is in contact with the upper surface of each of the plurality of contacts C12 on the lower surface.

The conductor 31 is located above the conductor L8. The conductor 31 has a plate-like shape along the xy plane. The conductor 31 functions as at least a part of a select gate line SGDL. The lower surface of the conductor 31 is exposed at the edge and has a terrace.

An insulator 32 is located on the upper surface of the conductor 31. The insulator 32 has a plate-like shape along the xy plane.

The conductors 33 and the insulators 34 are stacked one by one alternately on the upper surface of the insulator 32. The conductors 33 and the insulators 34 have a plate-like shape along the xy plane. Each conductor 33 functions as at least a part of the word line WL. FIG. 5 illustrates an example where n, that is, the number of memory cell transistors MT is 8. The conductors 33 function as at least a part of the word lines WL0, WL1, WL2, WL3, WL4, WL5, WL6, and WL7 in order from the bottom. The lower surface of each conductor 33 is exposed at the edge and has a terrace.

The insulator 35 is located on the upper surface of the uppermost conductor 33.

The conductor 36 is located on the upper surface of the insulator 35. The conductor 36 functions as at least a part of a select gate line SGSL.

The insulator 37 is located on the upper surface of the conductor 36. The conductor 38 is located on the upper surface of the insulator 37. The lower surface of the conductor 38 is exposed at the edge and has a terrace.

The memory pillars MP extend along the z axis and penetrate the set of the conductors 31, 33, and 36, and the insulators 32, 34, 35, and 37. Each memory pillar MP includes an insulator CI, a semiconductor SM, and a layer stack SS. The semiconductor SM covers the side surface of the insulator CI. The layer stack SS covers the side surface of the semiconductor SM. The layer stack SS is open at the upper end of the memory pillar MP. Part of the semiconductor SM is located in the opening and is in contact with the conductor 38 on the upper surface.

The upper part of the memory pillar MP may be located inside the conductor 38, the layer stack SS may be open in a portion facing the conductor 38, and part of the semiconductor SM may be located inside the opening.

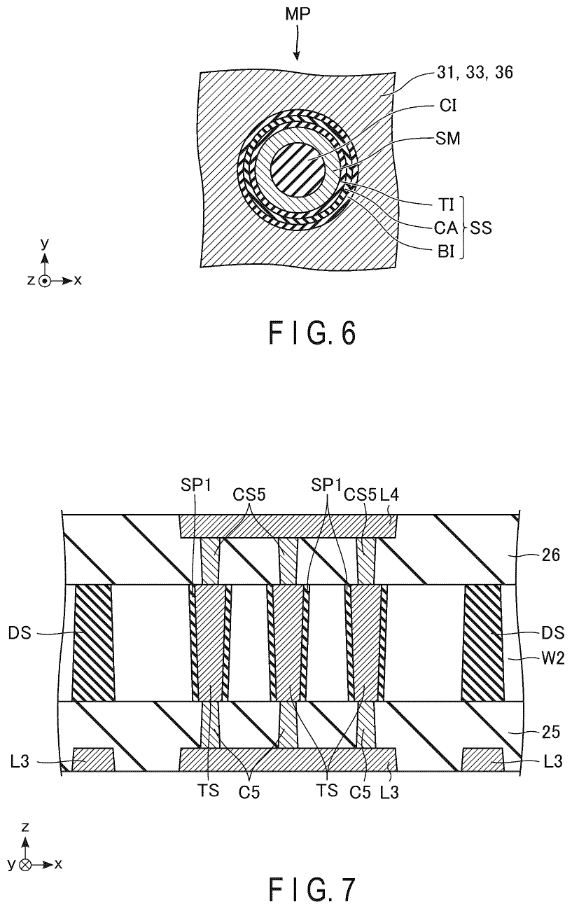

FIG. 6 illustrates an example of a cross-sectional structure of the memory pillar of the memory device of the first embodiment along the xy plane. As illustrated in FIG. 6, in one example, the layer stack SS includes a tunnel insulator TI, a charge accumulation film CA, and a block insulator BI.

The tunnel insulator TI surrounds the side surface of the semiconductor SM. The charge accumulation film CA surrounds the side surface of the tunnel insulator TI. The block insulator BI surrounds the side surface of the charge accumulation film CA. The conductor 31, 33 or 36 surrounds the side surface of the block insulator BI.

The semiconductor SM functions as a channel (current path) for the memory cell transistor MT and the select gate transistors DT and ST. Each of the tunnel insulator TI and the block insulator BI includes, for example, silicon oxide. The charge accumulation film CA accumulates charge. The charge accumulation film CA includes, for example, silicon nitride.

Referring back to FIG. 5, the part of each memory pillar MP that faces the conductor 31 functions as a single select gate transistor DT. The part of the memory pillar MP that faces the conductor 33 functions as a single memory cell transistor MT. The part of the memory pillar MP that faces the conductor 36 functions as a single select gate transistor ST. The lower surface of the semiconductor SM is exposed on the lower surface of each memory pillar MP. The upper surface of the semiconductor SM is exposed on the upper surface of each memory pillar MP.

Each contact C13 is in contact with the upper surface of a single conductor L8 on the lower surface. A plurality of contacts C13 in the connection region PA is in contact with the upper surface of a single conductor L8 on respective lower surfaces. Each of several contacts C13 is in contact with the lower surface of the semiconductor SM of a single memory pillar MP on the upper surface. Each of several contacts C13 is in contact with the lower surface of the terrace portion of a single conductor of the conductors 31, 33, and 37 on the upper surface.

The insulator 40 ranges from the level of the upper surface of the insulator 29 to the level of the upper surface of the conductor 38. The insulator 40 fills the region of the third structure 300 where components are not provided, that is, the region where the contacts C11, C12, and C13, the conductors L7, L8, 31, 33, 36, 38, the insulators 40, 32, 34, 35, 37, and the memory pillar MP are not provided.

The insulator 41 is located on the upper surface of each of the conductor 38 and the insulator 40. The insulator 41 has an opening OG in the connection region PA. The opening OG ranges from the upper surface to the lower surface of the insulator 41. The opening OG reaches a plurality of contacts C13 in the connection region PA. The opening OG includes the external connection terminal PD therein. In one example, the external connection terminal PD is any one of the external connection terminals PD_D0, PD_D1, PD_D2, PD_D3, PD_D4, PD_D5, PD_D6, and PD_D7, which transmit and receive the input/output signals DQ. The external connection terminal PD is in contact with the upper surface of each of the plurality of contacts C13 on the lower surface.

Of the third structure 300, the part from the layer of the insulator 29 and the joint terminal BD3 to the layer of the conductor 38 may hereinafter be referred to as a first part 300a of the third structure 300.

### 1.1.3. Structure of Connection Region

FIG. 7 illustrates an example of a partial sectional structure of the memory device of the first embodiment. FIG. 7 is an enlarged view of the region in which the vias TS are provided in the substrate W2 in FIG. 5 (that is, connection region PA) and regions above and below the region.

As illustrated in FIG. 7, the conductor L3 and the contacts C5 have an inverted tapered shape. In a case where a component has an inverted tapered shape, this means that a certain length (or width) of the component along the xy plane increases from the upper end to the lower end of the component. That is, the length (or width) of the upper end of a certain component along a certain imaginary straight line is greater than the length (or width) of the lower end of the component along the imaginary straight line.

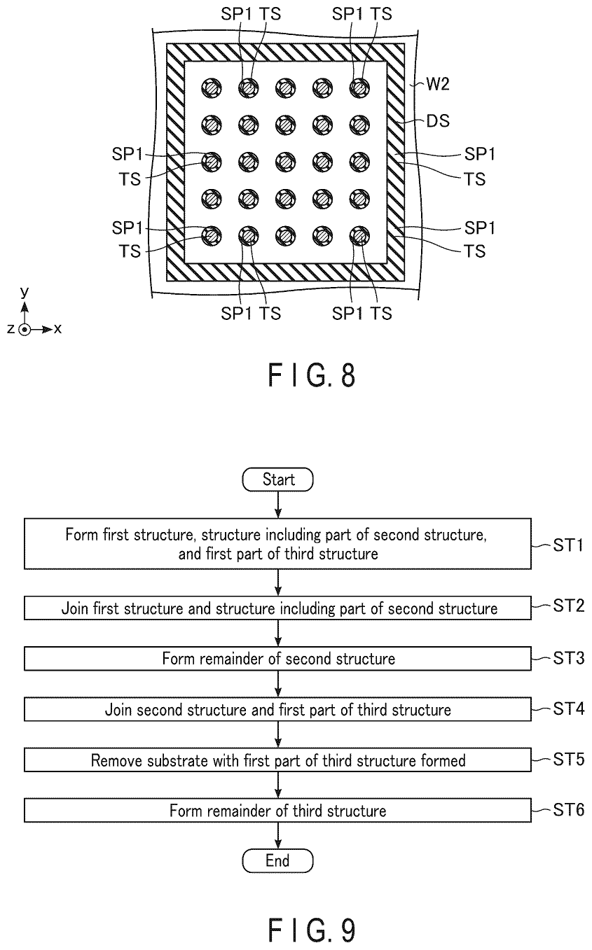

The isolation structure DS has an inverted tapered shape. The isolation structure DS extends along the xy plane, as will be described below with reference to FIG. 8. The length of the isolation structure DS along a direction intersecting the direction in which the isolation structure DS extends (i.e., X direction or Y direction) increases from the upper end to the lower end.

The via TS has a tapered shape. In a case where a component has a tapered shape, this means that a certain length (or width) of the component along the xy plane decreases from the upper end to the lower end of the component. That is, the length (or width) of the upper end of a certain component along a certain imaginary straight line is smaller than the length (or width) of the lower end of the component along the imaginary straight line.

The contact CS5 and the conductor L4 have a tapered shape.

FIG. 8 is a plan view of a portion of the memory device of the first embodiment. FIG. 8 illustrates the structure of the region in which the vias TS are provided in the substrate W2 (that is, connection region PA), as viewed from the Z direction.

As described above with reference to FIG. 6 and illustrated in FIG. 8, a plurality of sets of the via TS and the insulator SP1 is provided. FIG. 8 illustrates, by way of example, sets arranged in a matrix with five rows along the x axis and five columns along the y axis.

The isolation structure DS surrounds the sets of the via TS and the insulator SP1 along the xy plane. The isolation structure DS has a linear shape and extends continuously along the xy plane. With this structure of the isolation structure DS, the isolation structure DS electrically isolates the part of the substrate W2 that is surrounded by (that is, inside) a splitting structure from the outside part of the splitting structure of the substrate W2. The width of the isolation structure DS, that is, the length (or width) along an imaginary line that intersects with the direction in which the splitting structure extends has a size that is sufficient to suppress the capacitance (or electrostatic capacitance) between the region inside the isolation structure and the region outside the isolation structure DS. As the width increases, the capacity is suppressed, but this leads to an increase in the area of the memory device 1. Therefore, the isolation structure DS has a width determined based on the suppression of the capacity by the isolation structure DS and the allowable area of the splitting structure WS.

### 1.2. Method of Manufacturing

FIG. 9 illustrates an example of a flow of a method of manufacturing the memory device of the first embodiment. As illustrated in FIG. 9, the first structure 100, a structure including a part of the second structure 200, and the first part 300a of the third structure 300 are formed (step ST1). The first structure 100, the structure including a part of the second structure 200, and the first part 300a of the third structure 300 are formed by separate processes.

In one example, the first structure 100 is formed by forming the components located in the Z direction from the substrate W1 on the substrate W1 in order in the Z direction.

The structure including a part of the second structure 200 includes the structure from the substrate W2 to the joint terminal BD2L and the insulator 24. In one example, the structure including a part of the second structure 200 is formed by the following method. First, the substrate W2 is prepared in a state of being inverted with respect to the xy plane from the orientation illustrated in FIG. 5, that is, prepared with the upper side illustrated in FIG. 5 facing downward. Next, on the upper surface (lower surface in FIG. 5) of the substrate W2, the structure from the substrate W2 to the joint terminal BD2L and the insulator 24 is formed.

The first part 300a of the third structure 300 is formed in one example by the following method. First, a substrate W3 (not illustrated) is prepared. Next, on the upper surface of the substrate W3, the structure is formed that is inverted with respect to the xy plane from the orientation of the first part 300a illustrated in FIG. 5, that is, the structure in which the upper side of the structure illustrated in FIG. 5 faces downward is formed. In one example, the part of the structure closer to the substrate W3 is formed earlier.

The first structure 100 and the structure including a part of the second structure 200 are joined (or bonded) (step ST2). With the structure including a part of the second structure 200 inverted with respect to the xy plane, the joining is performed such that the joint terminal BD1 of the first structure 100 and the joint terminal BD2L of the structure including a part of the second structure 200 are in contact with each other.

The remainder of the second structure 200 is formed (step ST3). The method of forming the remainder of the second structure 200 will be described in more detail below. The forming includes the forming of the joint terminal BD2U of the second structure 200.

The second structure 200 and the first part 300a of the third structure 300 are joined (or bonded) (step ST4). With the first part 300a of the third structure 300 inverted with respect to the xy plane, the joining is performed such that the joint terminal BD2U of the second structure 200 and the joint terminal BD3 of the first part 300a of the third structure 300 are in contact with each other.

The substrate W3 on which the third structure 300 is formed is removed (step ST5). Examples of the removal include chemical mechanical polishing (CMP). The substrate W3 may remain by being thinned instead of being removed.

The remainder of the third structure 300 is formed (step ST6). This completes the structure illustrated in FIG. 5.

### 1.2.1. Method of Manufacturing Second Structure

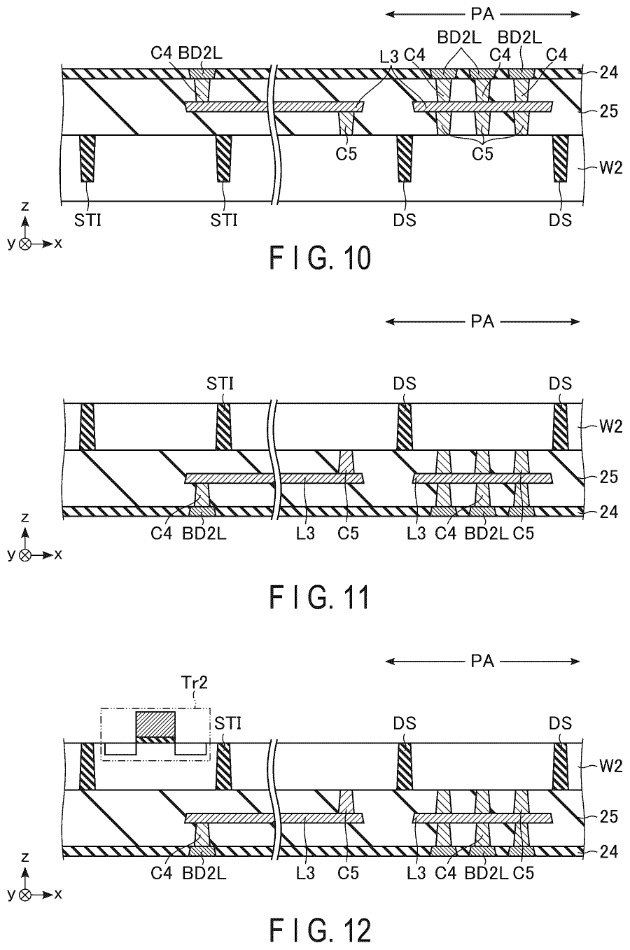

FIGS. 10 to 15 illustrate examples of states during the manufacturing of a part of the memory device of the first embodiment in order. FIGS. 10 to 15 illustrate one example of states during the manufacturing of the second structure 200.

FIG. 10 illustrates the process performed as a part of step ST1 of the flow of FIG. 9. As illustrated in

FIG. 10, the substrate W2 is prepared in a state inverted with respect to the xy plane from the orientation illustrated in FIG. 5, that is, prepared with the upper side as illustrated in FIG. 5 facing downward. The STI and the isolation structure DS are formed in the region including the upper surface of the substrate W2 (that is, lower surface in FIG. 5). In one example, the STI and the isolation structure DS are formed by a common process. That is, a trench is formed in the region including the upper surface of the substrate W2, by a set of the lithography process and anisotropic etching. Examples of the etching method include reactive ion etching (RIE). Then, the trench is filled with the material for the STI and the isolation structure DS. Due to the use of the anisotropic etching, the STI and the isolation structure DS have a tapered shape.

Above the substrate W2, the structure is formed from the upper surface of the substrate W2 to the layer of the joint terminal BD2L and the insulator 24, that is, the contacts C5 and C4, the conductor L3, the joint terminal BD2L, and the insulators 25 and 24 are formed.

FIGS. 11 to 15 illustrate the process performed as a part of step ST3 of the flow of FIG. 9. As illustrated in FIG. 11, the structure formed by the processes up to this point, that is, the structure including a part of the second structure 200 is inverted with respect to the xy plane. As a result, the isolation structure DS now has an inverted tapered shape. Then, the substrate W2 is thinned by partially removing the upper surface (or, surface opposite to the side where the insulator 25 is located). Examples of the method of removal include chemical mechanical polishing (CMP). The removal is performed until the STI and the isolation structure DS are exposed.

As illustrated in FIG. 12, the transistor Tr2 is formed.

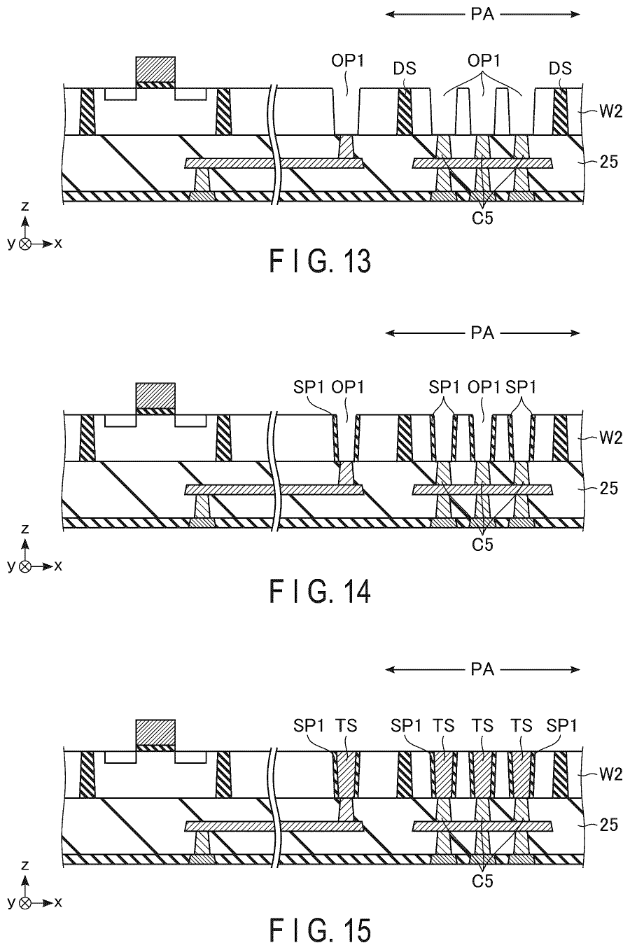

As illustrated in FIG. 13, openings OP1 are formed by partially removing the substrate W2. Each opening OP1 is formed in the region where each set of the via TS and the insulator SP1 is to be formed. Each opening OP1 reaches the lower surface from the upper surface of the substrate W2. Each opening OP1 exposes the upper surface of each contact C5 and a part of the upper surface of the insulator 25. Examples of the method of forming the opening OP1 include a set of the lithography process and the anisotropic etching such as RIE. Due to the use of the anisotropic etching, the opening OP1 has a tapered shape.

As illustrated in FIG. 14, the insulator SP1 is formed on the side surface of the opening OP1, that is, on the part of the surface of the substrate W2 that is exposed by the opening OP1. Specifically, first, the insulator SP1 is deposited on the side surface and the bottom surface of the opening OP1, that is, on the exposed part in the opening OP1 out of the surface of the substrate W2 and the surface of the insulator 25, and on the upper surface of the contact C5. Examples of the method of deposition include chemical vapor deposition (CVD). Then, the bottom part of the opening OP1 in the insulator SP1 is removed by the set of the lithography process and the anisotropic etching such as RIE.

As illustrated in FIG. 15, the remaining part of the opening OP1 is filled with the via TS. Based on the shape of the opening OP1, each set of the via TS and the insulator SP1 has a tapered shape.

After this, as illustrated in FIG. 5, the remainder of the second structure 200, that is, the structure from the substrate W to the layer of the joint terminal BD2U and the insulator 27 is formed. This provides the second structure 200.

### 1.3. Advantages (Advantageous Effects)

According to the first embodiment, as described below, the memory device that can operate at high speed can be provided.

To increase the capacity of the memory device, the memory device can include the plurality of joined structures such as the first structure 100, the second structure 200, and the third structure 300. In such a structure, to electrically couple the components in the separate structures to each other, some structure needs to include the vias that penetrate a substrate, such as the vias TS. These vias form parasitic capacitance with the substrate surrounding the vias. The parasitic capacitance reduces the speed of signals passing through the vias. The request for high speed operation of the memory device, in particular, requirements for input/output signals of the memory device is high, and the parasitic capacitance has a great influence. If the isolation structure DS as in the first embodiment is not provided, parasitic capacitance is formed between each via TS and the rest of the substrate W2. Since the insulator SP1 is thin, the parasitic capacitance of each via TS is large. By thickening the insulator SP1 around the via TS, the parasitic capacitance can be reduced. However, to achieve sufficient suppression of the parasitic capacitance, the area of the insulator SP1 needs to increase significantly. To thicken the insulator SP1, it may also be necessary to increase the spacing of the via TS.

According to the first embodiment, the isolation structure DS that surrounds the plurality of vias TS coupled in parallel is provided. Therefore, the inside region (that is, region where the vias TS are located) and the outside region of the isolation structure DS in the substrate W2 are electrically isolated. Therefore, the capacitance formed by the outside region of the isolation structure DS is isolated from the inside region. Therefore, the parasitic capacitance of the vias TS is suppressed. Therefore, the memory device 1 that can operate at high speed can be provided.

According to the first embodiment, the isolation structure DS surrounds the plurality of vias TS. Therefore, by newly providing a single isolation structure DS, the parasitic capacitance of the plurality of vias TS can be reduced. Therefore, by providing the isolation structure DS with a large width while suppressing the increase in the area due to the newly provided isolation structure DS, the parasitic capacitance can be significantly reduced.

### 1.4. Modifications

### 1.4.1. Modification 1

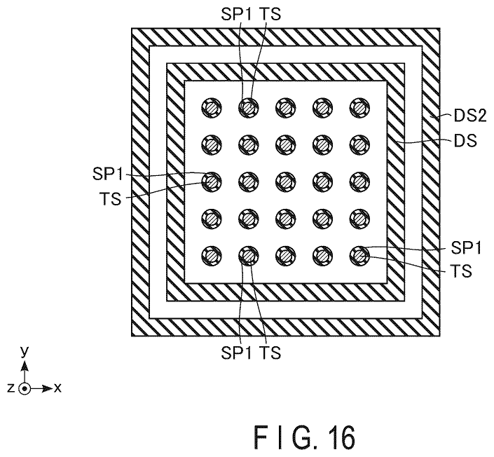

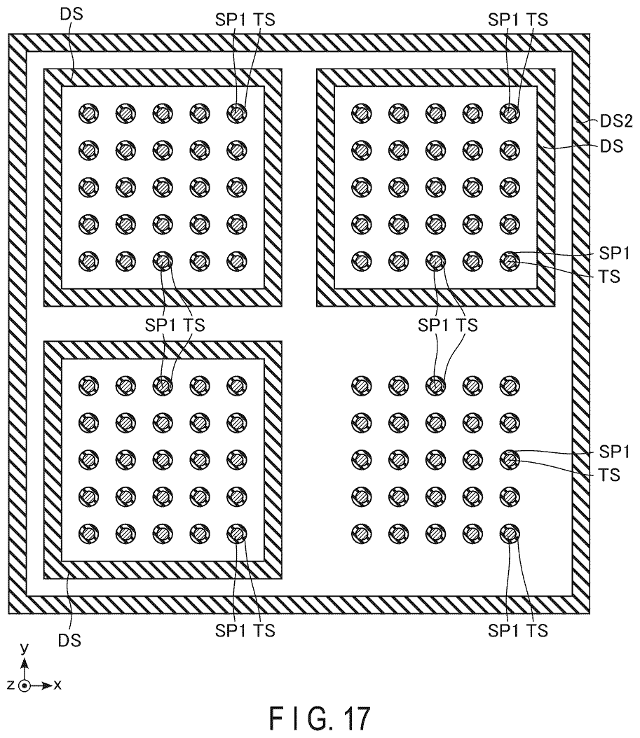

FIGS. 16 and 17 are each a plan view of a part of the memory device of modification 1 of the first embodiment. FIGS. 16 and 17 illustrate the structure of the region in which the vias TS are provided in the substrate W2 (that is, connection region PA), as viewed from the Z direction.

As illustrated in FIGS. 16 and 17, the isolation structure DS may be disposed in multiple locations. That is, in the example of FIG. 16, an isolation structure DS2 is further provided, and the isolation structure DS2 surrounds the isolation structure DS along the xy plane. In the example of FIG. 17, a single isolation structure DS2 surrounds the plurality of isolation structures DS along the xy plane. In the example of FIG. 17, several sets of the via TS and the insulator SP1 are not surrounded by the isolation structure DS, but are surrounded by a single isolation structure DS2.

### 1.4.2. Modification 2

The orientation of each of the first structure 100, the second structure 200, and the third structure 300 is not limited to the orientation illustrated in FIGS. 3 and 5, but may be any orientation.

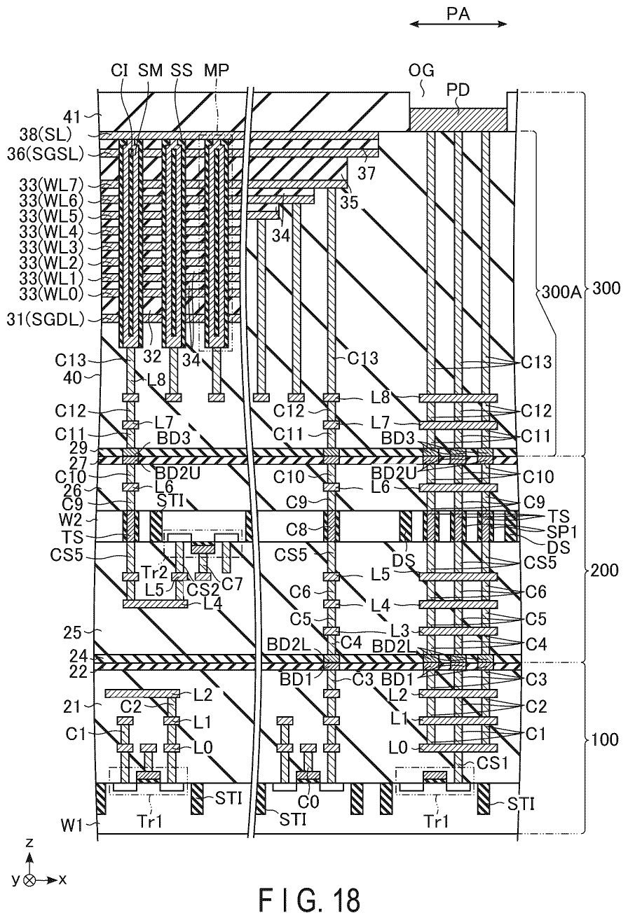

FIG. 18 illustrates an example of a partial sectional structure of the memory device of modification 2 of the first embodiment. As illustrated in FIG. 18, the second structure 200 has an opposite orientation to the orientation illustrated in FIG. 5 with respect to the xy plane. That is, each conductor L4 is in contact with the upper surface of each of a single contact C5 on the lower surface. A single conductor L4 in the connection region PA is in contact with the upper surface of each of the plurality of contacts C5 on the lower surface.

Each contact C6 is in contact with the upper surface of a single conductor L4 on the lower surface. A plurality of contacts C6 in the connection region PA is in contact with the upper surface of a single conductor L4 on respective lower surfaces.

Each conductor L5 is in contact with the upper surface of a single contact C6 on the lower surface. A single conductor L5 in the connection region PA is in contact with the upper surface of each of the plurality of contacts C6 on the lower surface.

Each contact CS2 is in contact with the upper surface of a single conductor L5 on the lower surface. Each contact CS5 is in contact with the upper surface of a single conductor L5 on the lower surface. A plurality of contacts CS5 in the connection region PA is in contact with the upper surface of a single conductor L4 on respective lower surfaces.

The substrate W2 is located in a layer above the layer of the contacts CS2 and CS5.

The transistor Tr2 is located in the region below and near the lower surface of the substrate W2. The transistor Tr2 includes a gate insulator on the lower surface of the substrate W2, a gate electrode on the lower surface of the gate insulator, and a pair of source/drain regions sandwiching the region above the gate electrode. Each gate electrode is in contact with the upper surface of a single contact C7 on the lower surface. Each of the source/drain regions is in contact with the upper surface of a single contact CS2 on the lower surface.

Each via TS is in contact with the upper surface of a single contact CS5 on the lower surface.

The insulator 25 ranges from the level of the upper surface of the joint terminal BD2L and the upper surface of the insulator 24 to the level of the upper surface of the contact C8. The insulator 25 fills the region where the contacts C4, C5, C6, C7, CS2, and CS5, the conductors L3, L4, and L5, and the transistor Tr2 are not provided in the region above the joint terminal BD2L and the insulator 24.

Each contact C9 is in contact with the upper surface of a single via TS on the lower surface.

Each conductor L6 is in contact with the upper surface of a single contact C9 on the lower surface. A single conductor L6 in the connection region PA is in contact with the upper surface of each of a plurality of contacts C9 on the lower surface.

Each contact C10 is in contact with the upper surface of a single conductor L6 on the lower surface. A plurality of contacts C10 in the connection region PA is in contact with the upper surface of a single conductor L6 on respective lower surfaces.

The insulator 26 ranges from the level of the upper surface of the substrate W2 to the level of the upper surface of the contact C10. The insulator 26 fills the region from the level of the upper surface of the substrate W2 to the level of the upper surface of the contact C10 where components are not provided, that is, the region where the contacts C9 and C10 and the conductor L6 are not provided.

Each joint terminal BD2U is in contact with the upper surface of a single contact C10 on the lower surface.

### 1.4.3. Modification 3

The arrangement of the first structure 100, the second structure 200, and the third structure 300 is not limited to the arrangement illustrated in FIGS. 3 and 5, but may be any arrangement.

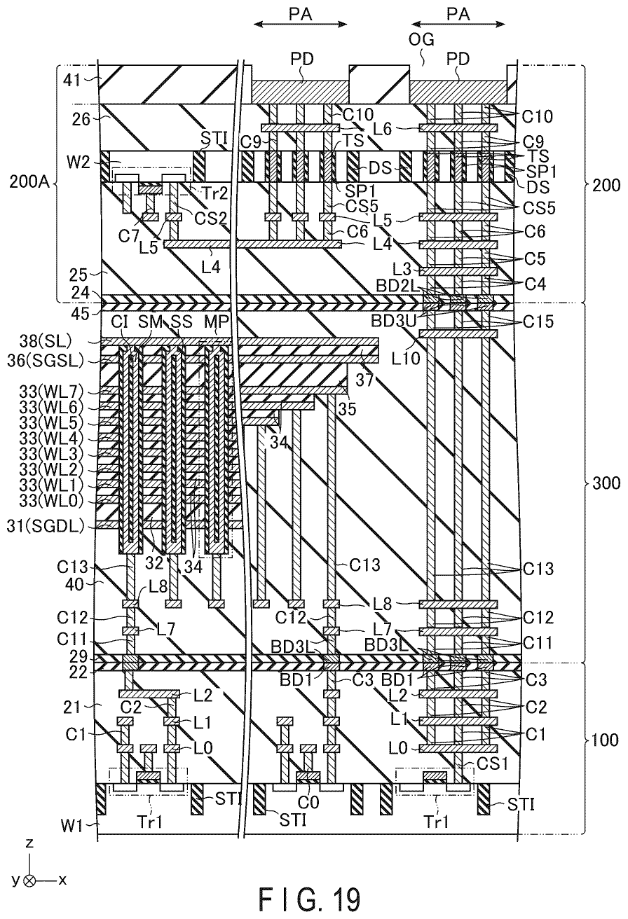

FIG. 19 illustrates an example of a partial sectional structure of the memory device of modification 3 of the first embodiment. As illustrated in FIG. 19, the third structure 300 is located on the upper surface of the first structure 100, and the second structure 200 is located on the upper surface of the third structure 300. The second structure 200 has the same orientation as the orientation of the second structure 200 in modification 2.

The third structure 300 includes the joint terminal BD3L in place of the joint terminal BD3, and further includes the joint terminal BD3U in place of the external connection terminal PD. The third structure 300 further includes a contact C15, a conductor L10, and an insulator 45.

Each contact C11 is in contact with the upper surface of a single joint terminal BD3L on the lower surface.

The plurality of contacts C13 in the connection region PA is in contact with the lower surface of a single conductor L8 on the upper surface, in place of the external connection terminal PD.

The contact C15 is in contact with the upper surface of a single conductor L10 on the lower surface. A plurality of contacts C15 in the connection region PA is each in contact with a single conductor L10 on the lower surface.

Each contact C15 is in contact with the lower surface of a single joint terminal BD3U on the upper surface.

The insulator 45 fills the region in the layer in which the joint terminal BD3U is located where the joint terminal BD3U is not provided.

Each joint terminal BD3U is in contact with the lower surface of a single joint terminal BD2L on the upper surface.

The second structure 200 further includes the external connection terminals PD and the insulator 41. Each external connection terminal PD is in contact with the upper surface of each of the plurality of contacts C10 on the lower surface.

### 2. Second Embodiment

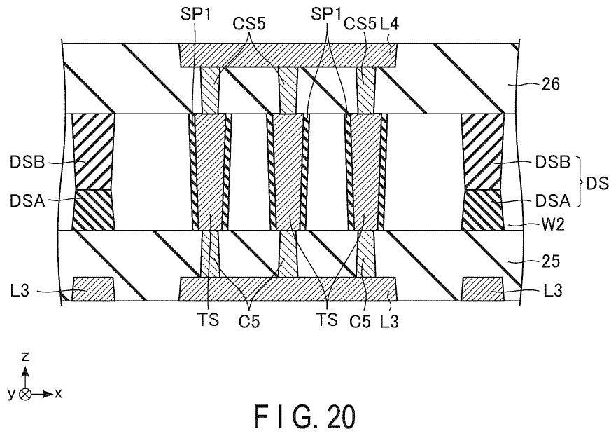

FIG. 20 illustrates an example of a partial sectional structure of a second embodiment. FIG. 20 illustrates the same region as in FIG. 7 of the first embodiment.

As illustrated in FIG. 20, each isolation structure DS includes a first part DSA and a second part DSB. The first part DSA occupies the lower part including the lower surface of the isolation structure DS. The second part DSB is located on the upper surface of the first part DSA. The second part DSB occupies the part including the upper surface of the isolation structure DS. The first part DSA has an inverted tapered shape. The second part DSB has a tapered shape. In one example, the first part DSA and the second part DSB include silicon oxide.

The overall flow of the method of manufacturing a structure of a memory device of the second embodiment is the same as the flow in FIG. 9 of the first embodiment.

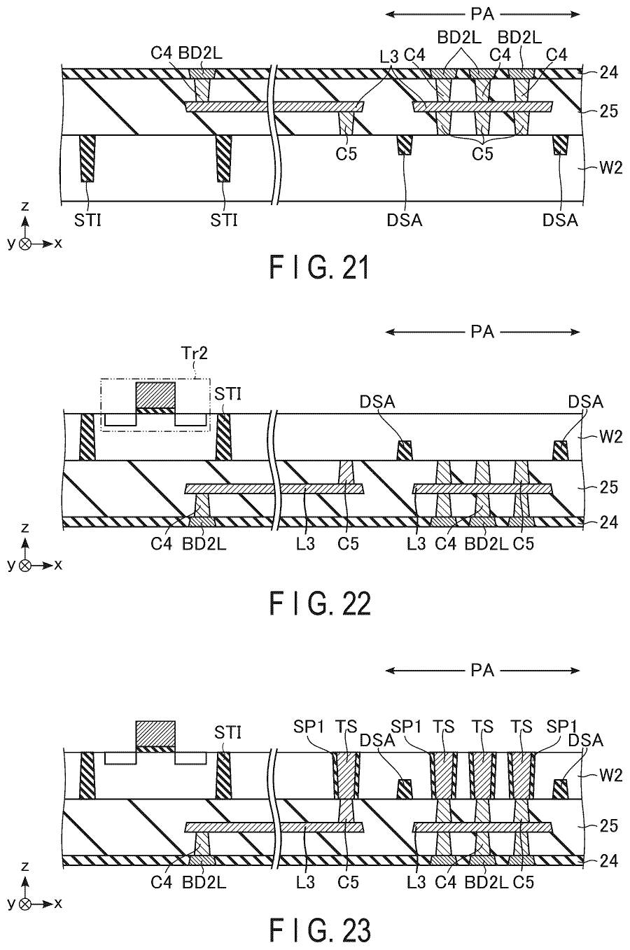

FIGS. 21 to 25 illustrate examples of states during the manufacturing of a part of the memory device of the second embodiment in order. FIGS. 21 to 25 illustrate one example of states during the manufacturing of a second structure 200 in order. The difference from the first embodiment will be described below.

FIG. 21 illustrates the process performed as a part of step ST1 of the flow of FIG. 9. In the process illustrated in FIG. 21, in a connection region PA, in place of the isolation structure DS in the process illustrated in FIG. 5, the first part DSA of the isolation structure DS is formed. Examples of the method of formation include, as well as forming STI, forming a trench by a set of the lithography process and the anisotropic etching, and filling the trench with a material for the first part DSA. Due to the use of the anisotropic etching, the first part DSA of the isolation structure DS has a tapered shape.

FIGS. 22 to 25 illustrate the process performed as a part of step ST3 of the flow of FIG. 9. As illustrated in FIG. 22, the structure formed by the processes up to this point, that is, the structure including a part of the second structure 200 is inverted with respect to the xy plane, and is joined to a first structure 100. As a result, the first part DSA of the isolation structure DS now has an inverted tapered shape. Then, a transistor Tr2 is formed.

As illustrated in FIG. 23, vias TS and insulators SP1 are formed. The method of forming the vias TS and the insulators SP1 is the same as the method described above with reference to FIGS. 13 to 15 in the first embodiment.

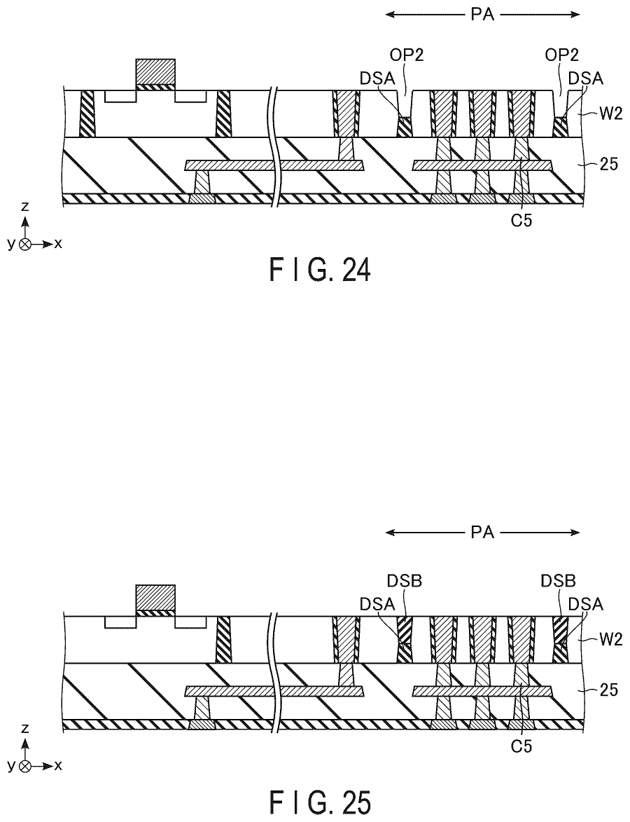

As illustrated in FIG. 24, openings OP2 are formed by partially removing a substrate W2. Each opening OP2 is formed in the region in which the second part DSB of the isolation structure DS is to be formed. Each opening OP2 reaches from the upper surface of the substrate W2 to the upper surface of the first part DSA of the isolation structure DS. Examples of the method of forming the opening OP2 include a set of the lithography process and the anisotropic etching such as RIE. Due to the use of the anisotropic etching, the opening OP2 has a tapered shape.

As illustrated in FIG. 25, the opening OP2 is filled with the material for the second part DSB of the isolation structure DS. This completes the isolation structure DS.

The process thereafter is the same as the process of the first embodiment.

The process described above with reference to FIG. 24 may be performed prior to the process described above with reference to FIG. 23. That is, the opening OP2 is formed, and then the vias TS and the insulators SP1 are formed.

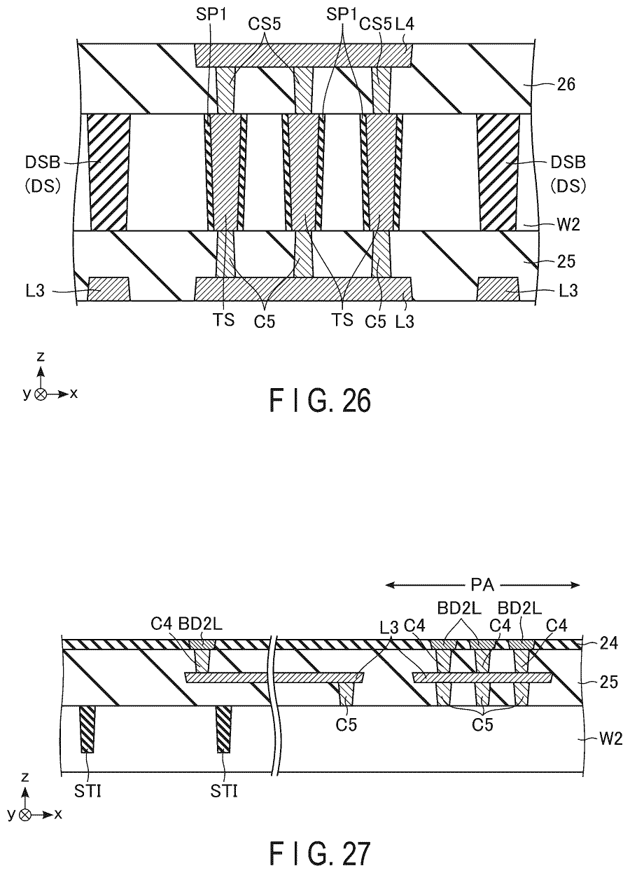

The isolation structure DS may include only the second part DSB. FIG. 26 illustrates an example of a partial sectional structure of the memory device of a modification of the second embodiment. FIG. 26 illustrates the same region as in FIG. 20 and FIG. 7 of the first embodiment. As illustrated in FIG. 26, that is, the isolation structure DS includes the second part DSB that reaches from the upper surface to the lower surface of the substrate W2.

The structure of FIG. 26 can be formed by the following manufacturing process. FIGS. 27 to 31 illustrate one example of states during the manufacturing of a part of the memory device of the modification of the second embodiment in order. FIGS. 27 to 31 illustrate one example of states during the manufacturing of the second structure 200 of the modification. The difference from the first embodiment will be described below.

FIG. 27 illustrates the process performed as a part of step ST1 of the flow of FIG. 9. In the process illustrated in FIG. 27, the isolation structure DS is not formed in the connection region PA. This structure includes a part of the second structure 200.

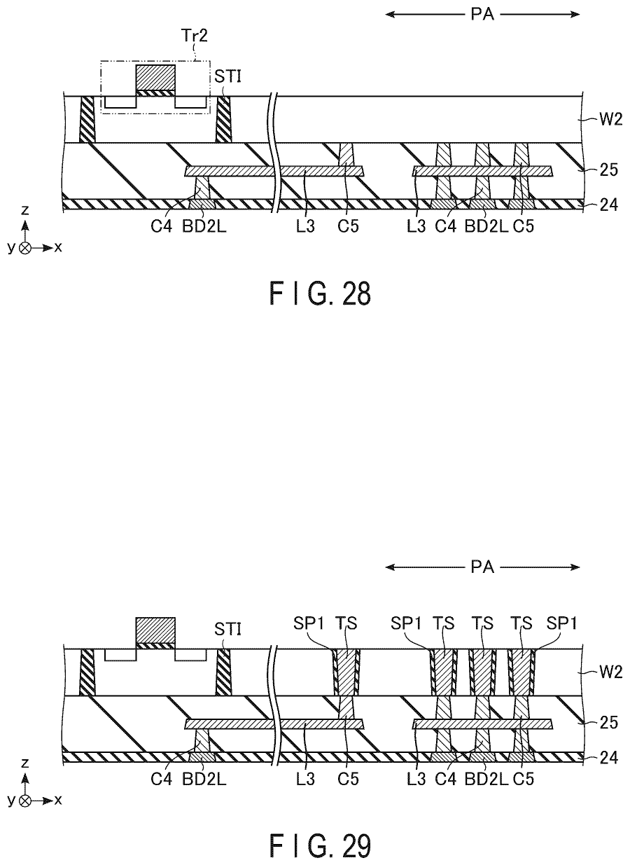

FIGS. 28 to 31 illustrate the process performed as a part of step ST3 of the flow of FIG. 9. As illustrated in FIG. 28, the structure formed by the processes up to this point, that is, the structure including a part of the second structure 200 is inverted with respect to the xy plane, and is joined to the first structure 100. Then, a transistor Tr2 is formed.

As illustrated in FIG. 29, the vias TS and the insulators SP1 are formed. The method of forming the vias TS and the insulators SP1 is the same as the method described above with reference to FIGS. 13 to 15 in the first embodiment.

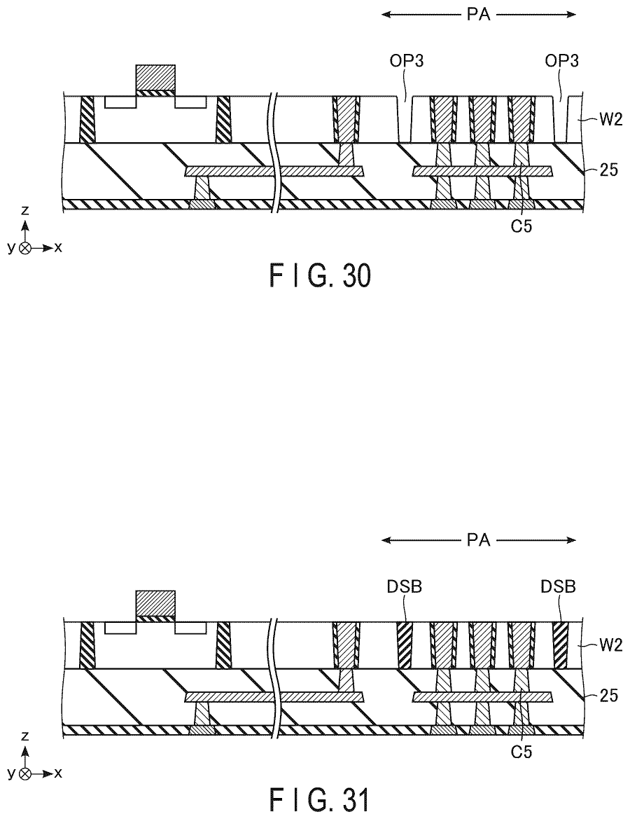

As illustrated in FIG. 30, openings OP3 are formed by partially removing the substrate W2. Each opening OP3 is formed in the region in which the second part DSB of the isolation structure DS is to be formed. Each opening OP3 reaches the lower surface from the upper surface of the substrate W2. Examples of the method of forming the opening OP3 include a set of the lithography process and the anisotropic etching such as RIE. Due to the use of the anisotropic etching, the opening OP3 has a tapered shape.

As illustrated in FIG. 31, the opening OP3 is filled with the material for the second part DSB of the isolation structure DS. This completes the isolation structure DS.

The process thereafter is the same as the process of the first embodiment.

The process described above with reference to FIG. 30 may be performed prior to the process described above with reference to FIG. 29. That is, the opening OP3 is formed, and then the vias TS and the insulators SP1 are formed.

Modification 1, 2, or 3 of the first embodiment may be applied to the second embodiment.

In the process described above with reference to FIG. 25, the opening OP2 may be filled through the formation of an insulator 26. In this case, the second part DSB of the isolation structure DS includes the same material as the insulator 26.

The insulator SP1 and the second part DSB may be formed by a common process. That is, after the process described above with reference to FIG. 25, in the process of forming the opening for the via TS and the insulator SP1, the opening OP2 is also formed. The opening OP2 is filled in the subsequent process for the formation of the insulator SP1.

The second embodiment provides the same advantages as advantages obtained by the first embodiment.

### 3. Third Embodiment

The third embodiment is based on the second embodiment. The third embodiment differs from the second embodiment in terms of the structure of a second part DSB of an isolation structure DS.

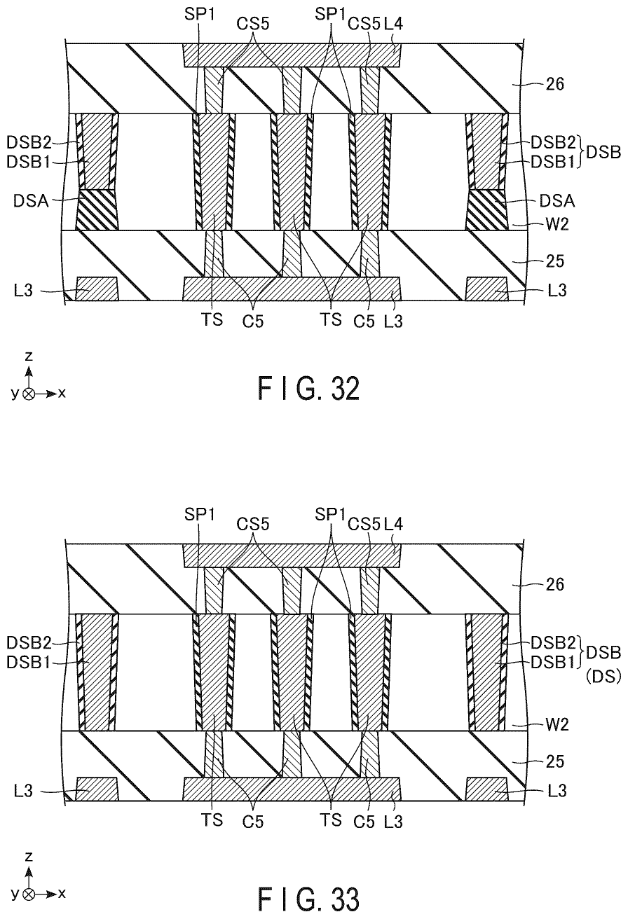

FIG. 32 illustrates an example of a partial section of the third embodiment. FIG. 32 illustrates the same region as in FIG. 7 of the first embodiment.

As illustrated in FIG. 32, the second part DSB includes a conductor DSB1 and an insulator DSB2. The conductor DSB1 extends along the z axis and occupies the region that includes the center of the second part DSB2. In one example, the conductor DSB1 includes the same material as the material for a via TS. The insulator DSB2 covers the side surface of the conductor DSB1.

The structure illustrated in FIG. 32 can be formed by the common process with the process for forming the set of the via TS and an insulator SP1. That is, in the process described above with reference to FIG. 23 of the second embodiment, before filling the materials for the via TS and the insulator SP1, an opening OP2 as described above with reference to FIG. 24 of the second embodiment is formed. The opening OP2 may be formed by the process separate from the formation of an opening for the set of the via TS and the insulator SP1, or may be formed by a common process. Thereafter, the insulator DSB2 is formed by the common process with the process for the formation of the insulator SP1, and the conductor DSB1 is formed by the common process with the process for the formation of the via TS.

The modification of the second embodiment may be applied to the third embodiment. That is, as illustrated in FIG. 33, the isolation structure DS includes the second part DSB that reaches from the upper surface to the lower surface of a substrate W2, and the second part DSB includes the conductor DSB1 and the insulator DSB2.

Modification 1, 2, or 3 of the first embodiment may be applied to the third embodiment.

The third embodiment also provides the same advantages as the first embodiment.

### 4. Fourth embodiment

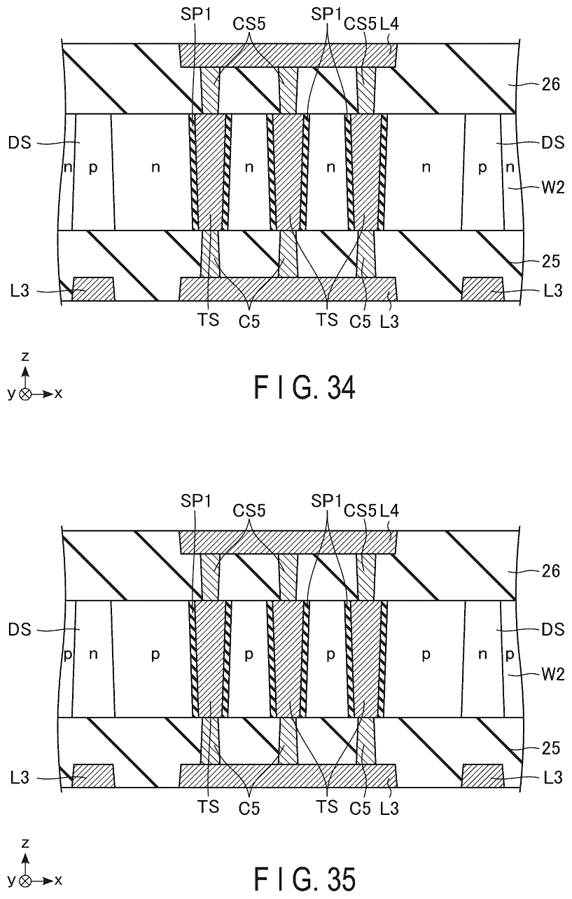

FIGS. 34 and 35 illustrate examples of a partial sectional structure of a fourth embodiment. FIGS. 34 and 35 illustrate the same region as in FIG. 7 of the first embodiment.

As illustrated in FIG. 34, an isolation structure DS includes a diffusion region of p-type impurities. A substrate W2 contains n-type impurities. Examples of p-type impurities include boron (B). Examples of n-type impurities include arsenic (As).

As illustrated in FIG. 35, the isolation structure DS may include a diffusion region of n-type impurities, while the substrate W2 may contain p-type impurities.

In one example, the isolation structure DS can be formed by ion implantation before the formation of a contact C5 in the process described above with reference to FIG. 10 of the first embodiment.

Modification 1, 2, or 3 of the first embodiment may be applied to the fourth embodiment.

The fourth embodiment provides the same advantages as advantages obtained by the first embodiment.

### 5. Other Modifications

The memory device 1 may further include one or

more fourth structures similar to the second structure 200.

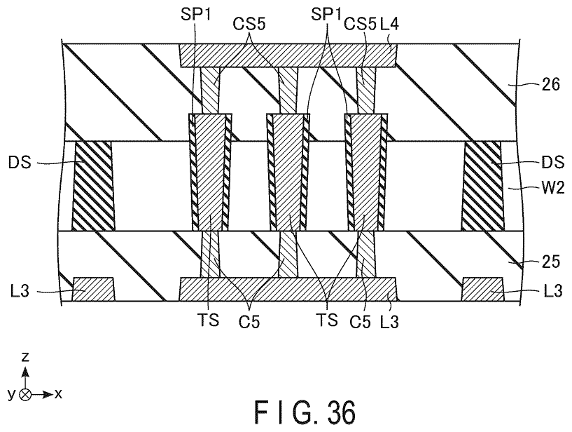

The structure of the via TS and the insulator SP1 is not limited to the structure illustrated in FIG. 7, and may have the structure illustrated in FIG. 36. That is, the upper part of the via TS and the upper part of the insulator SP1 protrude from the upper surface of the substrate W2. Such a structure results, for example, from the process below. That is, in the process illustrated in FIG. 13, a mask is formed on the upper surface of the substrate W2, and using the mask, the opening OP is formed by the lithography process and the anisotropic etching described above with reference to FIG. 13. Then, with the mask remaining in place, the via TS and the insulator SP1 are formed, and then the mask is removed. As a result, the via TS and the insulator SP1 protrude from the upper surface of the substrate W2 by the thickness of the region where the mask existed. The structure illustrated in FIG. 36 shows an example based on FIG. 7 about the basic form of the first embodiment. However, the structure illustrated in FIG. 36 can also be applied to the modification of the first embodiment, the second embodiment, the third embodiment, and the fourth embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first substrate;
a first transistor on the first substrate;
a second substrate above the first transistor;
an external connection terminal above the second substrate;
a second transistor on the second substrate;
a first conductor that penetrates the second substrate and electrically couples the first transistor to the external connection terminal;
a first isolation structure that, as viewed from a first direction, is ring-shaped and surrounds the first conductor, penetrates the second substrate, and isolates the second substrate; and
a memory cell array electrically coupled to the first transistor and the second transistor.

2. The memory device according to claim 1, wherein
the first isolation structure includes a first insulator that penetrates the second substrate in the first direction.

3. The memory device according to claim 2, wherein
the second substrate includes a first surface and a second surface that are positioned opposite to each other in the first direction, and
a length of the first insulator along a second direction intersecting with a direction in which the first insulator extends increases from a side of the first surface of the second substrate toward a side of the second surface of the second substrate.

4. The memory device according to claim 3, further comprising
a second insulator provided in the second substrate and surrounding the second transistor,
wherein a length of the second insulator along the second direction increases from a side of the first surface of the second substrate toward a side of the second surface of the second substrate.

5. The memory device according to claim 4, wherein
a length of the first conductor along the second direction decreases from a side of the first surface of the second substrate toward a side of the second surface of the second substrate.

6. The memory device according to claim 1, wherein the first isolation structure includes:
a third insulator; and
a fourth insulator on a side of the third insulator in the first direction.

7. The memory device according to claim 6, wherein
the second substrate includes a first surface and a second surface that are positioned opposite to each other in the first direction,
a length of the third insulator along a second direction intersecting with a direction in which the third insulator extends increases from a side of the first surface of the second substrate toward a side of the second surface of the second substrate, and
a length of the fourth insulator along the second direction decreases from a side of the first surface of the second substrate toward a side of the second surface of the second substrate.

8. The memory device according to claim 7, further comprising
a second insulator provided in the second substrate and surrounding the second transistor,
wherein a length of the second insulator along the second direction increases from a side of the first surface of the second substrate toward a side of the second surface of the second substrate.

9. The memory device according to claim 8, wherein
a length of the first conductor along the second direction decreases from a side of the first surface of the second substrate toward a side of the second surface of the second substrate.

10. The memory device according to claim 6, wherein
the first isolation structure further includes a second conductor, and
the third insulator surrounds the second conductor.

11. The memory device according to claim 10, wherein
the second substrate includes a first surface and a second surface that are positioned opposite to each other in the first direction, and
a length of the second conductor along a second direction intersecting with a direction in which the second conductor extends decreases from a side of the first surface of the second substrate toward a side of the second surface of the second substrate.

12. The memory device according to claim 11, further comprising
a second insulator provided in the second substrate and surrounding the second transistor,
wherein a length of the second insulator along the second direction increases from a side of the first surface of the second substrate toward a side of the second surface of the second substrate.

13. The memory device according to claim 12, wherein
a length of the first conductor along the second direction decreases from a side of the first surface of the second substrate toward a side of the second surface of the second substrate.

14. The memory device according to claim 1, wherein
the second substrate contains first conductivity type impurities, and
the first isolation structure contains second conductivity type impurities different from the first conductivity type impurities.

15. The memory device according to claim 1, further comprising
a second isolation structure that surrounds the first isolation structure as viewed from the first direction.

16. The memory device according to claim 1, further comprising:
a first structure including a first terminal;
a second structure that is in contact with the first structure on a side of the first direction from the first structure, includes a second terminal that is in contact with the first terminal, and includes a third terminal that is electrically coupled to the second terminal; and
a third structure that is in contact with the second structure on a side of the first direction from the second structure, and includes a fourth terminal that is in contact with the third terminal and is electrically coupled to the external connection terminal.

17. The memory device according to claim 1, further comprising
a plurality of first conductors that includes the first conductor, penetrates the second substrate, and electrically couples the first transistor to the external connection terminal.

18. A method of manufacturing a memory device, the method comprising:
forming a first structure including a first substrate, a first transistor on the first substrate, and a first conductor in contact with the first substrate, the forming of the first structure including forming a ring-shaped first isolation structure that surrounds a first region of the first substrate in the first substrate;
joining a second structure including a second substrate and a second transistor on the second substrate to the first structure;
forming a second conductor that penetrates the first substrate and is in contact with the first conductor in the first region; and
forming a third structure including a memory cell array electrically coupled to the first transistor and the second transistor, and an external connection terminal electrically coupled to the second conductor.

19. The method of manufacturing a memory device according to claim 18, wherein
forming the first isolation structure includes forming a first insulator in an opening extending from a first surface of the first substrate.

20. The method of manufacturing a memory device according to claim 19, further comprising
forming a second isolation structure in the first substrate after the joining of the second structure and the first structure, the second isolation structure extending from a surface opposite to the first surface and in contact with the first isolation structure.
